(19) United States
(12) Patent Application Publication
(10) Pub. No.: US 2018/0158949 A1
(43) Pub. Date: Jun. 7, 2018

(54) SPACER FORMATION IN VERTICAL FIELD EFFECT TRANSISTORS

(71) Applicant: International Business Machines Corporation, Armonk, NY (US)

(72) Inventors: Kangguo Cheng, Schenectady, NY (US); Juntao Li, Cohoes, NY (US); Geng Wang, Stormville, NY (US)

(21) Appl. No.: 15/900,827

(22) Filed: Feb. 21, 2018

Related U.S. Application Data
(63) Continuation of application No. 15/364,355, filed on Nov. 30, 2016.

(51) Int. Cl. H01L 29/78; H01L 29/66

(52) U.S. Cl. CPC H01L 29/7827; H01L 29/66666; H01L 29/6656

(57) ABSTRACT

Embodiments of the present invention provide systems and methods for generating oxide spacers in a vertical field transistor. The fin of the channel facilitates the electrical current flowing between the source terminal and the drain terminal. By employing sacrificial spacers, implanted oxidation enhancement species on a silicon surface, an implanted oxidation enhancement species can be oxidized to oxide spacers.

### BACKGROUND OF THE INVENTION

The present invention relates generally to semiconductor fabrication, and more specifically to depositing oxides in field effect transistors.

Semiconductor device fabrication is a series of processes used to create integrated circuits present in electronic devices, such as computers. Silicon is most frequency used as a semiconducting material in order to construct wafers. More specifically with respect to semiconductor device fabrication, these wafers behave as the substrate on which a series of photo-lithographic and chemical processing steps are performed. Some of the photolithographic and chemical processing steps involve doping (i.e., the addition of impurities to pure semiconducting materials to modulate electrical conducting properties of a device); ion implantation (i.e., the acceleration of ions of a material within an electrical field, wherein the ions impinge upon the solid); etching (i.e., the chemical removal of layers from the surface of a wafer); deposition of materials on a wafer (i.e., the controlled synthesis of materials as thin films); and photolithographic patterning (i.e., the patterning of the bulk portion of a wafer and/or parts of a thin film, which have been deposited on a wafer).

### SUMMARY

According to one embodiment of the present invention, a method comprising: modifying a silicon surface beneath a fin structure; oxidizing one or more portions of the modified silicon surface to form a first set of oxide spacers; depositing a silicon gate structure around the one or more portions of the fin structure, wherein the silicon gate structure has a top layer; and forming a second set of oxide spacers from the top layer of the silicon gate structure.

Another embodiment of the present invention provides a first vertical field effect transistor containing a first set of oxide spacers and a second set of oxide spacers, based on the method above.

### BRIEF DESCRIPTION OF THE DRAWINGS

FIG. 1 is a block diagram of a semiconductor fabrication environment, in accordance with an embodiment of the present invention;

FIG. 2 is a functional block diagram of FIN structures, in accordance with an embodiment of the present invention;

FIG. 3 is a functional block diagram of FIN structures incorporating sacrificial spacers, in accordance with an embodiment of the present invention;

FIG. 4 is a functional diagram of a silicon substrate incorporating implanted oxidation enhancement species layers on a silicon surface, in accordance with an embodiment of the present invention;

FIG. 5 is a functional block diagram of a silicon substrate incorporating selectively deposited SiGe layers on a silicon surface, in accordance with an embodiment of the present invention;

FIG. 6 is a functional block diagram illustrating a resultant structure upon oxidation of the implanted oxidation enhancement species layer, in accordance with an embodiment of the present invention;

FIG. 7 is a functional block diagram illustrating a resultant structure upon oxidation of the selectively deposited SiGe layer, in accordance with an embodiment of the present invention;

FIG. 8A is a functional block diagram of an added dummy silicon gate to the spacers formed via oxidation of the implanted oxidation enhancement species layer, in accordance with an embodiment of the present invention;

FIG. 8B is a functional block diagram of an added dummy silicon gate to the spacers formed via oxidation of the selectively deposited SiGe layer, in accordance with an embodiment of the present invention;

FIG. 9A is a functional block diagram of a subsequent oxidation of another implanted oxidation enhancement species layer or selectively deposited SiGe layer on the dummy silicon gate, in accordance with an embodiment of the present invention;

FIG. 9B is a functional block diagram of a subsequent oxidation of another implanted oxidation enhancement species layer or selectively deposited SiGe layer on the dummy silicon gate, in accordance with an embodiment of the present invention;

FIG. 10 is a functional block diagram of the resultant VFET structure upon resuming further semiconductor fabrication processes, in accordance with an embodiment of the present invention;

FIG. 11 is an operational flowchart to generate spacers through two oxidations, wherein an oxidation enhancement species layer is oxidized in the first oxidation, in accordance with an embodiment of the present invention; and

FIG. 12 is an operational flowchart to generate spacers through two oxidations, wherein an epitaxial SiGe layer is oxidized in the first oxidation, in accordance with an embodiment of the present invention.

### DETAILED DESCRIPTION

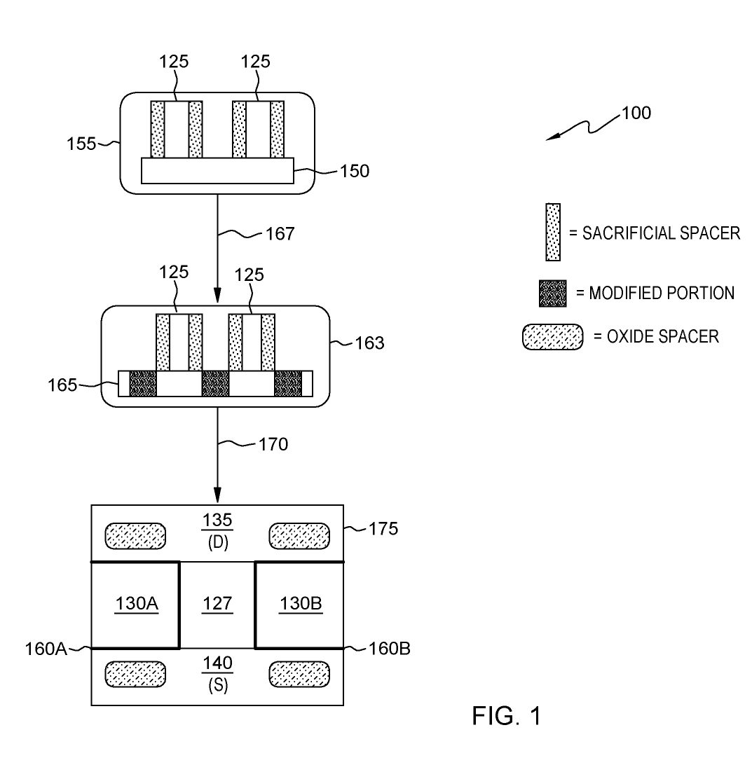

In semiconductor manufacturing, vertical field effect transistors (VFET) are being pursued as viable architectures to be incorporated into a complimentary metal-oxide-semiconductor (CMOS) which transcends beyond a 7 nm node (i.e., a technology node as defined by the International Technology Roadmap for Semiconductors). Thus, conventional oxide spacer formation, which involves deposition of material onto a wafer and reactive-ion etching (i.e., a type of etching which uses a chemically reactive plasma, which contains high-energy ions that impinge upon a wafer surface and subsequently react with the wafer surface), is not obtainable in a VFET, wherein the oxide spacer is horizontally oriented (see FIG. 1). Embodiments of the present disclosure describe solutions to enable oxide spacer formation on the bottom of the source/drain component within a VFET through the application of self-limiting oxidation (which also assists in controlling the thickness of the formed spacer) at low temperatures on the following entities: (i) the oxidation enhancement species (e.g., fluorine) implantation on an oxidation enhancement layer (OEL); or (ii) the selectively deposited silicon/germanium (SiGe) layer.

The present invention will now be described in detail with reference to the Figures. FIG. 1 is a block diagram of a semiconductor fabrication environment, in accordance with an embodiment of the present invention. FIG. 1 provides only an illustration of implementation and does not imply any limitations with regard to the environments in which different embodiments may be implemented.

Semiconductor fabrication environment 100 depicts block diagrams of components necessary to implement the methods and systems as disclosed by the embodiments of the present invention. Additional types of components may be used without departing from the scope of the invention as recited by the claims. The electronic components, depicted in FIG. 1, are arranged in particular configurations in conjunction with other wires, voltage sources, data sources, etc., in order to enable semiconductor fabrication processes. Semiconductor fabrication environment 100 depicts the precursor structures for constructing a vertical field effect transistor (VFET).

VFET 175 is the vertical field transistor, which is a type of metal-oxide semiconductor field-effect transistor (MOSFET) used for amplifying and switching electronic signals. More specifically, VFET 175 may be: (i) a n-channel MOSFET and thus uses electrons (as opposed to holes) for conduction or (ii) a p-channel MOSFET and thus uses holes (as opposed to electrons) for conduction. The electrons or holes move through channel 127. In other words, channel 127 acts as a conduit for transiting current required for electrical conduction via electrons or holes. VFET is a transistor device which contains four terminals—terminals 130A, 130B, 135, and 140. These terminals may be connected to data inputs, other wires, other electronic components, and/or devices. Terminals 130A and 130B are gate terminals; gate dielectrics 160A and 160B are gate oxides; terminal 140 is the source terminal; and terminal 135 is the drain terminal. Drain-to-source current flows (via a conducting channel) connects the source terminal (e.g., terminal 140) to the drain terminal (e.g., terminal 135).

The diagram of VFET 175 is a general schematic used to describe VFETs, wherein the VFETs contain metal oxide semiconductors instead of p-n junctions. There may be variations in the arrangements and structures of VFET 175 without departing from the scope of the invention. Even though isolation and electrical contact components are not depicted, these entities may be required for processing complementary metal oxide semiconductor (CMOS) based systems and other structures as disclosed in this invention. Terminal 130A, terminal 130B, terminal 135, terminal 140, and channel 127 each contain polysilicon or mono-silicon material which may be: (i) doped with n-type and/or p-type dopants, or (ii) un-doped. Channel 127 is a vertical silicon slit which serves as a narrow silicon passage between the two larger silicon based regions of terminal 140 (i.e., the source region) and terminal 135 (i.e., the drain region). Gate dielectric 160A and gate dielectric 160B are dielectric layers (i.e., electrical insulators) which separate gate terminals 130A and 130B, respectively, of a MOSFET from the underlying source terminal, drain terminal, and conductive channel that connects the source region and the drain region when the transistor is turned “on.” Conductive gate material is subsequently deposited over the gate oxide to furnish the transistor. More specifically, gate dielectric 160A is a boundary separating terminal 130A from terminal 135, terminal 140, and channel 127 while gate dielectric 160B is a boundary separating terminal 130B from terminal 135, terminal 140, and channel 127. Embodiments of the present invention enable oxide spacer formation in a VFET as depicted in VFET 175. The formations of these oxide spacers are desired by the providing at least the following function: insulate/isolate the gate terminals 130A and 130B from the source contacts (which are associated with terminal 140 as denoted by the “S” in VFET 175) and drain contacts (which are associated with terminal 135 as denoted by the “D” in VFET 175).

In an exemplary embodiment, channel 127 is constructed to behave as a FIN/finFET (i.e., fin 125 in fin system 155 and fin system 163), wherein channel 127 is a conductor of electric current between terminal 140 and terminal 135. Furthermore, a finFET version of channel 127 is surrounded on three sides by a thin semiconductor “fin” forming the gate of the transistor. This type of design of channel 127 typically refers to a transistor with two gates. For example, the two gates in FIG. 1 are terminal 130A and 130B. Terminal 135 biases the current source of VFET 175. Terminal 135 is connected to the drain of VFET 175. Terminals 130A and 130B are connected to the gates of VFET 175.

The precursor structures in semiconductor fabrication environment 100 are fin system 155 and fin system 163. Fin system 155 and fin system 163 contain fin 125, wherein each unit of fin 125 has two sidewalls. Each sidewall is attached to a sacrificial spacer and thus each unit of fin 125 incorporates two units of a sacrificial spacer. VFET 175 derives from fin system 163, wherein processing 170 on fin system 163 yields oxide spacers, as shown in VFET 175. Processing 167 on fin system 155 yields fin system 163. Process 167 are substrate modification processes, which includes: (i) the implantation of oxidation enhancement species (e.g., fluorine) layers; or (ii) the selective deposition of silicon germanium (SiGe) layers. Fin system 163 retains the sacrificial spacers and units of fin 125 within fin system 155. The difference between fin system 163 and fin system 155 is the silicon surface on which the units of fin 125 reside. Fin system 155 contains a silicon surface in the form of surface 150 whereas fin system 163 contains a silicon surface in the form of surface 165. The implanted oxidation enhancement species (e.g., fluorine) layers or the selectively deposited of SiGe layers on surface 150 yields surface 165, wherein silicon surface 165 contains modified portions as indicated in FIG. 1. In contrast, surface 150 does not contain any modified portions through implanted oxidation enhancement species or selectively deposited SiGe layers.

Processing 170 on fin system 163 lead to VFET 175. Processing 170 may include one or more of the following techniques/processes applied on a uniformly doped silicon wafer (i.e., semiconductor fabrication)—lithography; etching; deposition; oxidation; chemical mechanical planarization; ion implantation; and diffusion—to furnish integrated circuits, wherein the integrated circuits may contain multiple units of transistors. This is not an exhaustive list of techniques/processes included within processing 170 but rather a list of commonly used techniques as understood in the art. Furthermore, the term “processing 170” implies a device or set of devices or any type of equipment used to implement the said techniques/processes, as understood in the art.

Lithography is used to transfer a pattern from a photomask to the surface of the wafer. For example, the gate area of a MOS transistor is defined by a specific pattern. The pattern information is recorded on a layer of a photoresist which is applied on the top of the wafer. The physical properties of the photoresist change when exposed to light or another source of illumination. The photoresist is either developed by: (i) wet etching or dry etching; or (ii) converted portions of the photoresist to volatile compounds through the exposure of external entities. The pattern, as defined by the photomask, either is removed or remains after development depending on the type of photoresist.

Etching is used to remove material selectively in order to create patterns. The pattern is defined by the etching mask, because the parts of the material, which should remain, are protected by the mask. The unmasked material can be removed either by wet etching (i.e., chemical techniques) or dry etching (i.e., physical techniques). Wet etching is strongly isotropic and highly selective at creating pattern, wherein the etch rate greatly depends on the material being etched and does not damage the etched material. Dry etching is highly anisotropic but less selective, wherein dry etching is more conducive for transferring small structures in comparison to wet etching.

Deposition is utilized when a multitude of layers of different materials have to be deposited during the fabrication process of integrated circuits and transistors. During physical vapor deposition (PVD), accelerated gas ions sputter particles from a sputter target in a low pressure plasma chamber. During chemical vapor deposition (CVD), a chemical reaction takes place between gas mixtures on the substrate surface at high temperatures. During plasma enhanced chemical vapor deposition (PECVD), a rate of and the conversion of a chemical reaction between gas mixtures on the substrate surface is enhanced using radio frequencies, as opposed to high temperatures. CVD typically leads to deposited materials of more uniform thickness than PECVD.

Oxidation is a process which converts silicon on the wafer into silicon dioxide. The chemical reaction of silicon and oxygen commences at room temperature and stops upon yielding very a thin native oxide film, which is a readily formed product. For an effective oxidation rate, the wafer can be placed in an oxidation tool (e.g., a furnace) with oxygen or water vapor at elevated temperatures. Silicon dioxide layers are used as high-quality insulators or masks for ion implantation. The ability of silicon to form high quality silicon dioxide is a pivotal reason as to why silicon is a dominant material during semiconductor fabrication.

Chemical mechanical planarization (CMP) is used to impart increased planarity to the wafer surface with the aid of a chemical slurry. Other fabrication processes (e.g., etching, deposition, or oxidation) typically modify the topography of the wafer surface leading to a non-planar surface. CMP enables indirect patterning by virtue of material removal always starting on the highest areas of the wafer surface. Thus, at defined lower lying regions such as a trench oxide, the material remains unaffected. Together with the deposition of non-planar layers, CMP is an effective method to build up semiconducting structures.

Ion implantation is a technique to introduce dopant impurities into a crystalline silicon. This is performed with an electric field which accelerates the ionized atoms or molecules such that these particles penetrate into the target material until interactions with the silicon atoms are achieved. Ion implantation provides exact control of the distribution and the dose of the dopants in silicon, because the penetration depth depends on the kinetic energy of the ions, which is proportional to the electric field. The dose of the dopant can be controlled by varying the ion source. However, ion implantation may lead to crystal defects which need to be remedied.

Diffusion is the movement of dopants within a semiconductor material at high temperatures. The driving force of diffusion is the concentration gradient. There is a wide range of diffusivities for various dopant species, which depend on the ease with which the respective dopant impurity can move through the material. Diffusion is applied to anneal the crystal defects after ion implantation or to introduce dopant atoms into silicon from a chemical vapor source.

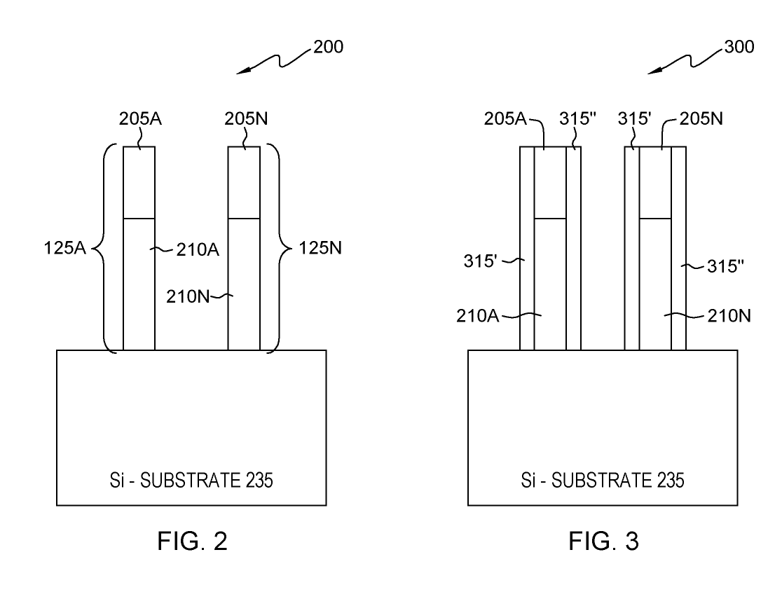

FIG. 2 is functional block diagram of FIN structures, in accordance with an embodiment of the present invention. FIG. 2 provides only an illustration of implementation and does not imply any limitations with regard to the environments in which different embodiments may be implemented.

Structure 200 is a first precursor to a VFET-type transistor containing oxide spacers. Si-substrate 235, which derives from the silicon wafer, includes monocrystalline silicon. On Si-substrate 235, there are multiple units of fin 125 and thus depicted as fin 125A to 125N in order to distinguish one unit of fin 125 from another unit of fin 125. Each unit of fin 125 contains hardmask 205 and mandrel 210. Hardmask 205 is depicted as hardmasks 205A to 205N in order to distinguish one unit of hardmask 205 from another unit of hardmask 205. Mandrel 210 is depicted as mandrels 210A to 210N in order to distinguish one unit of mandrel 210 from another unit of mandrel 210. Fin 125A contains hardmask 205A and mandrel 210A while fin 125N contains hardmask 205N and mandrel 210N. Fins can be formed by any suitable patterning technique such as lithography/etching, sidewall image transfer (SIT), etc. Each fin has a cap layer, wherein the cap layer is silicon nitride, silicon oxynitride, or any other suitable material.

FIG. 3 is a functional block diagram of FIN structures incorporating sacrificial spacers, in accordance with an embodiment of the present invention. FIG. 3 provides only an illustration of implementation and does not imply any limitations with regard to the environments in which different embodiments may be implemented.

Structure 300 is a second precursor to a VFET-type transistor containing oxide spacers. Structure 300 is the same as structure 200 except that structure 300 includes spacers 315′ and 315″. Hardmask 205 is depicted as hardmasks 205A to 205N in order to distinguish one unit of hardmask 205 from another unit of hardmask 205. Mandrel 210 is depicted as mandrels 210A to 210N in order to distinguish one unit of mandrel 210 from another unit of mandrel 210. A sacrificial spacer is a layer that is deposited over each unit of fin 125, wherein each unit of fin 125 is constructed of hardmask 205 and mandrel 210. For example, hardmask 205A and mandrel 210A construct fin 125A; and hardmask 205N and mandrel 210N construct fin 125N. The sacrificial spacer is subsequently etched back such that the spacer portion covering portions of fin 125 is etched away while the spacer portion on the sidewall of fin 125 remains as spacer 315′ and spacer 315″. In one embodiment, spacers 315′ and 315″ are present in tandem per unit of fin 125. Spacers 315′ and 315″ behave as sacrificial entities. Spacers 315′ and 315″ are constructed of silicon nitride, wherein the silicon nitride is able to protect dielectric 160 and fins 125A-N from oxidation during subsequent processing. The surface of Si-substrate 235 in structure 300 has not undergone any modifications via processing 167 or processing 170.

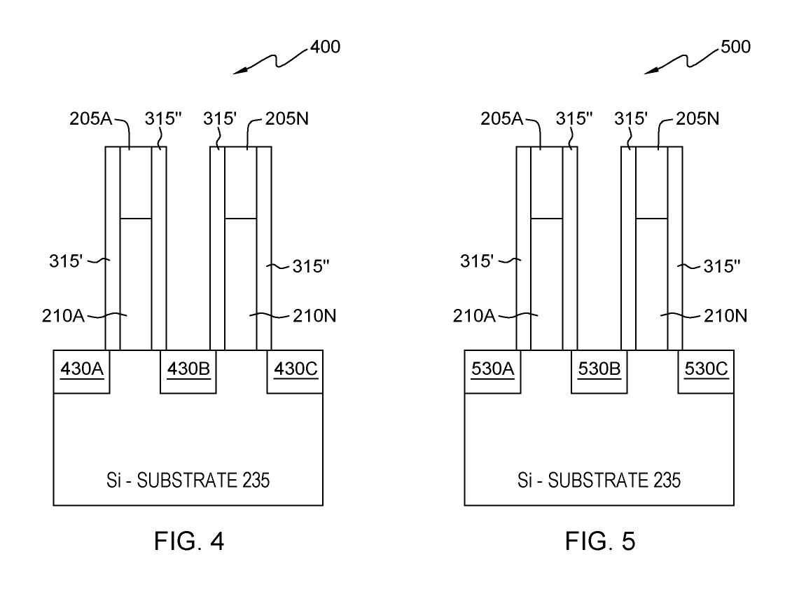

FIG. 4 is a functional diagram of a silicon substrate incorporating oxidation enhancement species layers on a silicon surface, in accordance with an embodiment of the present invention. FIG. 4 provides only an illustration of implementation and does not imply any limitations with regard to the environments in which different embodiments may be implemented.

Structure 400 is a third precursor to a VFET-type transistor containing oxide spacers residing on a gate oxide. Structure 400 is the same as structure 300 except that structure 400 includes oxidation enhancement layer (OEL) 430A, OEL 430B, and OEL 430C. Upon exposure in a chamber used in semiconductor fabrications, portions of Si-substrate 235 are exposed and can be modified by oxidation enhancement species (e.g., fluorine, germanium, and xenon), to generate the OELs 430A-C. OELs 430A-C are multiple units of OEL 430. In an exemplary embodiment, OELs 430A-C are formed on the silicon surface of Si-substrate 235 by implanting fluorine as the oxidation enhancement species (i.e., the ion implantation technique described with respect to processing 170 of FIG. 1). The implantation energy and dose required for implantation depend on the implantation species and the desired thickness of the implanted layer. In some embodiments, the fluorine implantation dose may range from 1E14/cm² to 1E15/cm²; the energy ranges from 0.5 keV to 5 keV. For an exemplary embodiment, fluorine containing entities are implanted into OELs 430A-C. In structure 400, the structural attributes of fin 125 (which is constructed of hardmask 205 and mandrel 210) and spacers 315′ and 315″ are resistant to modification by implanted fluorine on Si-substrate 235. In other words, hardmasks 205A-N and mandrels 210A-N are unaltered by processing 170. Hardmask 205 is depicted as hardmasks 205A and 205N in order to distinguish one unit of hardmask 205 from another unit of hardmask 205. Mandrel 210 is depicted as mandrels 210A and 210N in order to distinguish one unit of mandrel 210 from another unit of mandrel 210.

FIG. 5 is a functional block diagram of a silicon substrate incorporating selectively deposited SiGe layers on a silicon surface, in accordance with an embodiment of the present invention. FIG. 5 provides only an illustration of implementation and does not imply any limitations with regard to the environments in which different embodiments may be implemented.

Structure 500 is a fourth precursor to a VFET-type transistor containing oxide spacers. Structure 500 is the same as structure 300 except that structure 300 includes SiGe layers 530A, 530B, and 530C. Furthermore, structure 500 is the same as structure 400 except that structure 500 has SiGe layers as opposed to the enhanced oxidation species implanted into OELs 430A-C. In one embodiment, the SiGe layers are formed by epitaxial growth. SiGe layers 530A-C are multiple units of SiGe layer 530. This deposited film takes on a lattice structure and orientation identical to those observed in Si-substrate 235. In structure 400, the structural attributes of fin 125 (which is constructed of hardmask 205 and mandrel 210) and spacers 315′ and 315″ are resistant to modifications by depositing the film on Si-substrate 235. In other words, hardmasks 205A-N and mandrels 210A-N are unaltered by processing 170. Hardmask 205 is depicted as hardmasks 205A and 205N in order to distinguish one unit of hardmask 205 from another unit of hardmask 205. Mandrel 210 is depicted as mandrels 210A and 210N in order to distinguish one unit of mandrel 210 from another unit of mandrel 210.

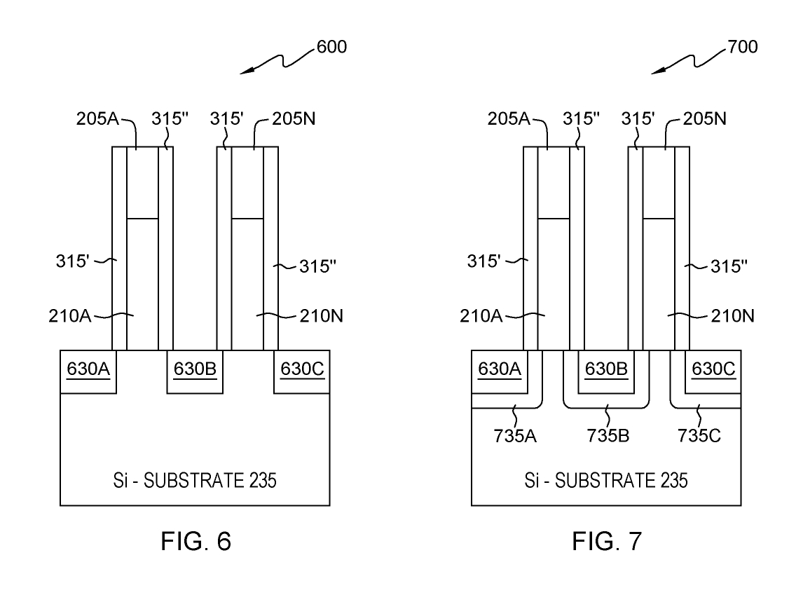

FIG. 6 is functional block diagram illustrating a resultant structure upon oxidation of the implanted oxidation enhancement species layer, in accordance with an embodiment of the present invention. FIG. 6 provides only an illustration of implementation and does not imply any limitations with regard to the environments in which different embodiments may be implemented.

Structure 600 is a fifth precursor to a VFET-type transistor containing oxide spacers. Structure 600 is the resultant structure upon oxidative conversion (i.e., the oxidation process in processing 170) of OELs 430A-C of structure 400, which contain the implanted oxidation enhancement species (e.g., fluorine). More specifically, bottom oxide spacer 630A, bottom oxide spacer 630B, and bottom oxide spacer 630C are formed by oxidizing OEL 430A of FIG. 4, OEL 430B of FIG. 4, and OEL 430C of FIG. 4, respectively. Bottom oxide spacers 630A-C are thin oxides with a thickness of 6 nm. Spacers 315′ and 315″ work in tandem to protect fins 125A-N from oxidation, wherein fin 125A contains hardmask 205A and mandrel 210A and fin 125N contains hardmask 205N and mandrel 210N. At relatively low temperatures (e.g., 450° C.-800° C. under dry or wet oxidation conditions), OELs 430A-C are oxidized to bottom oxide spacers 630A-C at a much faster rate than the un-implanted layers of Si-substrate 235. Bottom oxide spacers 630A-C are multiple units of bottom oxide spacer 630. There are two mechanisms by which the rate of oxidation can be enhanced by ion implantation. First, adding a species (e.g., fluorine and/or germanium) to silicon may chemically enhance the oxidation rate of the portion of silicon containing the species. Second, ion implantation may modify the silicon crystalline structure. For example, monocrystalline silicon can be made amorphous by ion implantation of an oxidation enhancement species (e.g., fluorine, germanium, xenon, and silicon). Amorphous silicon is much easier to oxidize than monocrystalline silicon. In other words, the oxidation rate of amorphous silicon is much greater than that of monocrystalline silicon. In an exemplary embodiment, OELs 430A-C of structure 400 contains oxidation enhancement species (e.g., fluorine) species and thus, OELs 430A-C impart amorphous character to Si-substrate 235. Furthermore, the oxidation rate of structure 400 (which contains OELs 430A-C) is much greater than structure 300 (which does not contain OELs 430A-C). By virtue of enhanced oxidation rates, conversion to bottom oxide spacers 630A-C may be achieved to furnish structure 600. The oxide spacer thickness may range from 3 nm to 10 nm, although greater and lesser thicknesses are also conceivable.

FIG. 7 is functional block diagram illustrating a resultant structure upon oxidation of the selectively deposited SiGe layer, in accordance with an embodiment of the present invention. FIG. 7 provides only an illustration of implementation and does not imply any limitations with regard to the environments in which different embodiments may be implemented.

Structure 700 is a sixth precursor to a VFET-type transistor containing oxide spacers. Structure 700 is the resultant structure upon oxidative conversion (i.e., the oxidation process in processing 170) of epitaxially grown SiGe layers 530A, 530B, and 530C of structure 500. More specifically, bottom oxide spacer 630A, bottom oxide spacer 630B, and bottom oxide spacer 630C are formed by oxidizing epitaxially grown SiGe layer 530A of FIG. 5, epitaxially grown SiGe layer 530B of FIG. 5, and epitaxially grown SiGe layer 530C of FIG. 5, respectively. Bottom oxide spacers 630A-C are thin oxides with a thickness of 6 nm. Furthermore, condensed regions 735A-C are formed in concert with bottom oxide spacers 630A-C, respectively. Condensed regions 735A-C are multiple units of condensed region 735. Germanium (Ge) condensation processes involves selectively oxidizing silicon over germanium of an epitaxial SiGe layer. Due to the effect of Ge condensation, the silicon of the epitaxial SiGe is oxidized and the remaining germanium is repelled by bottom oxide spacers 630A-C. The repulsion of Ge from bottom oxide spacers 630A, 630B, and 630C yields condensed regions 735A, 735B, and 735C, respectively. Spacers 315′ and 315″ work in tandem to protect fins 125A-N from oxidation, wherein fin 125A contains hardmask 205A and mandrel 210A and fin 125N contains hardmask 205N and mandrel 210N. At relatively low temperatures, epitaxially grown SiGe layers 530A, 530B, and 530C are oxidized to bottom oxide spacers 630A-C at a much faster rate than the underlying layers of Si-substrate 235. In an exemplary embodiment, epitaxially grown SiGe layers 530A-C of structure 500 contains SiGe species and thus, epitaxially grown SiGe layers 530A-C impart increased SiGe character to Si-substrate 235. Furthermore, the oxidation rate of structure 500 (which contains epitaxially grown SiGe layers 530A-C) is much greater than structure 300 (which does not contain epitaxially grown SiGe layers 530A-C). By virtue of enhanced oxidation rates, conversion to bottom oxide spacers 630A-C may be achieved to furnish structure 600. A dry or wet oxidation of the SiGe to bottom oxide spacers 630A-C can be achieved by furnace oxidation, rapid thermal oxidation, plasma enhanced oxidation, etc. at temperatures ranging from 450° C. to 1200° C. The oxidant may be oxygen gas, oxygen plasma, or steam (i.e., water vapor). Depending of the oxidation conditions (e.g., oxidant used, temperature, etc.), the time to complete the oxidative conversions ranges from 10 minutes to 1 hour.

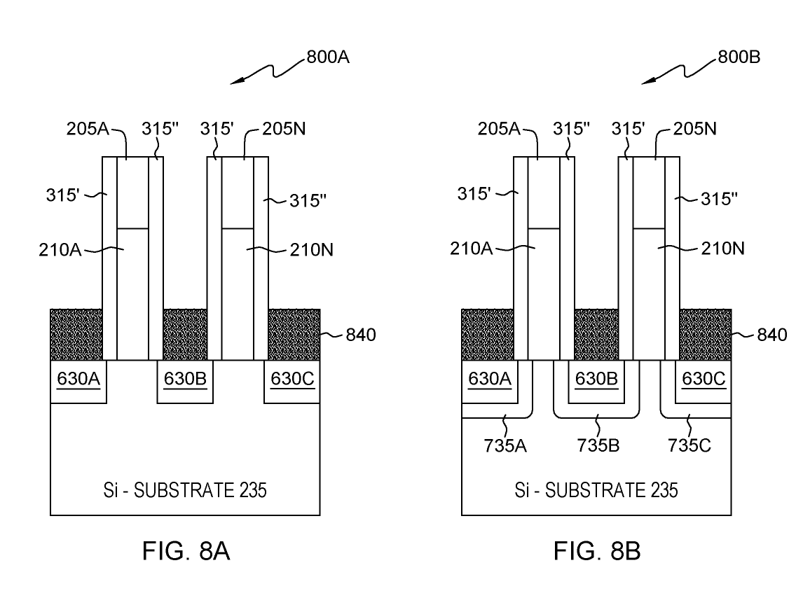

FIG. 8A is functional block diagram of an added gate to the spacers formed via oxidation of the implanted oxidation enhancement species layer, in accordance with an embodiment of the present invention. FIG. 8A provides only an illustration of implementation and does not imply any limitations with regard to the environments in which different embodiments may be implemented. In one embodiment, the gate is a dummy gate comprising a dielectric (e.g., silicon oxide) on the fin sidewalls and silicon on the gate dielectric.

Structure 800A is a seventh precursor to a VFET-type transistor containing oxide spacers residing on a gate oxide. Structure 800A is the same as structure 600 except that structure 800A includes silicon gate 840. Silicon gate 840 derives from amorphous silicon or polycrystalline silicon. Other fabrication processes (e.g., etching, deposition, or oxidation) typically modify the topography of the wafer surface leading to a non-planar surface. CMP (as described with respect to processing 170 in FIG. 1) and subsequent recessing of silicon gate 840 (i.e., receding surface levels off silicon gate 840) lead to a more planar and uniform surface of silicon gate 840, wherein the surface level is below the level of spacers 315′ and 315″ and hardmasks 205A-N. The addition of silicon gate 840 onto Si-substrate 235 does not structurally or chemically modify mandrels 210A-N; or bottom oxide spacers 630A, 630B, and 630C (i.e., the multiple units of bottom oxide spacer 630).

FIG. 8B is functional block diagram of an added gate to the spacers formed via oxidation of the SiGe layer, in accordance with an embodiment of the present invention. FIG. 8B provides only an illustration of implementation and does not imply any limitations with regard to the environments in which different embodiments may be implemented. In one embodiment, the gate is a dummy gate comprising a dielectric (e.g., silicon oxide) on the fin sidewalls and silicon on the gate dielectric.

Structure 800B is an eighth precursor to a VFET-type transistor containing oxide spacers. Structure 800B is the same as structure 700 except that structure 800B includes silicon gate 840. Silicon gate 840 derives from amorphous silicon. Other fabrication processes (e.g., etching, deposition, or oxidation) typically modify the topography of the wafer surface leading to a non-planar surface. CMP (as described with respect to processing 170 in FIG. 1) and subsequent recessing of silicon gate 840 (i.e., receding surface levels off silicon gate 840) lead to a more planar and uniform surface of silicon gate 840, wherein the surface level is below the level of spacers 315′ and 315″ and hardmasks 205A-N. The addition of silicon gate 840 onto Si-substrate 235 does not structurally or chemically modify mandrels 210A-N; bottom oxide spacers 630A, 630B, and 630C (i.e., the multiple units of bottom oxide spacer 630); or condensed regions 735A, 735B, and 735C (i.e., the multiple units of condensed region 735).

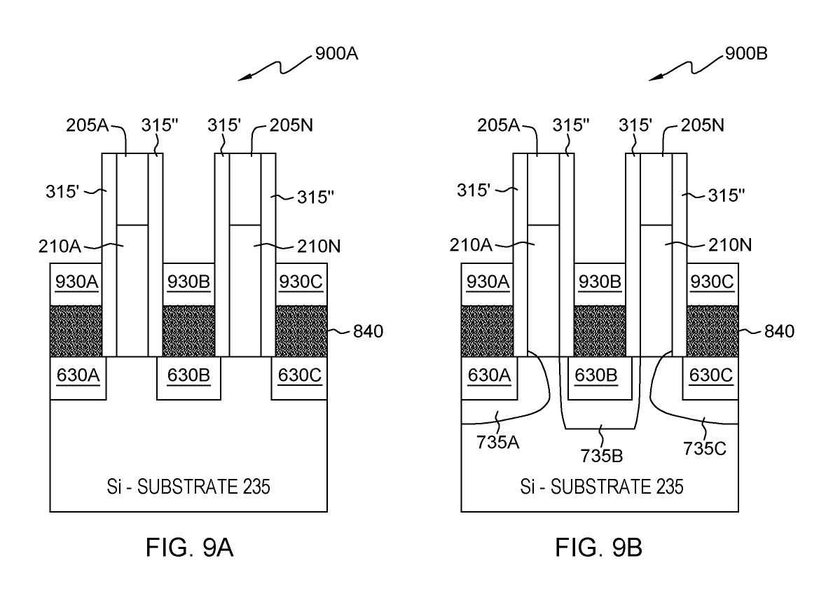

FIG. 9A is functional block diagram of a subsequent oxidation of another layer on the dummy silicon gate, in accordance with an embodiment of the present invention. FIG. 9A provides only an illustration of implementation and does not imply any limitations with regard to the environments in which different embodiments may be implemented.

Structure 900A is a ninth precursor to a VFET-type transistor containing oxide spacers. Structure 900A is the same as structure 800A except that structure 900A includes top oxide spacers 930A-C. In contrast to structure 900B, structure 900A does not contain condensed regions 735A-C. Another layer on silicon gate 840 is formed by (i) implanting an oxidation enhancement species (e.g., a fluorine ion) on the surfaces of the exposed portions of silicon gate 840; or (ii) selectively depositing SiGe on the surfaces of the exposed portions of silicon gate 840. Top oxide spacers 930A-C are formed by oxidizing this layer on silicon gate 840, which derives from: (i) the implanted oxidation enhancement species; or (ii) the selectively deposited SiGe. The oxidation of the exposed portions of silicon gate 840, does not lead to further chemical or structural modifications of Si-substrate 235; hardmasks 205A-N; mandrels 210A-N; or bottom oxide spacers 630A, 630B, and 630C (i.e., the multiple units of bottom oxide spacer 630). As stated above, hardmasks 205A-N and mandrels 210A-N construct fins 125A-N, respectively. Spacers 315′ and 315″ protect fins 125A-N (i.e., hardmasks 205A-N and mandrels 210A-N) from being converted into an oxidation product during the formation of top oxide spacers 930A-C. By adding the layer containing the implanted oxidation enhancement species or the selectively deposited SiGe, the oxidation rate of a structure containing the added layer (which derives from exposed portions of silicon gate 840) is greatly enhanced in comparison to the structure not containing said added layer. In other words, the increased content of oxidation enhancement species and SiGe facilitate these enhanced oxidation rates.

FIG. 9B is functional block diagram of a subsequent oxidation of another layer on the gate, in accordance with an embodiment of the present invention. FIG. 9B provides only an illustration of implementation and does not imply any limitations with regard to the environments in which different embodiments may be implemented.

Structure 900B is a tenth precursor to a VFET-type transistor containing oxide spacers residing on a gate oxide. Structure 900B is the same as structure 800B except that structure 900B includes top oxide spacers 930A-C. In contrast to structure 900A, structure 900B has condensed regions 735A, 735B, and 735C. Another layer on silicon gate 840 is formed by (i) implanting an oxidation enhancement species (e.g., a fluorine ion) on the surfaces of the exposed portions of silicon gate 840; or (ii) selectively depositing SiGe on the surfaces of the exposed portions of silicon gate 840. Top oxide spacers 930A-C are formed by oxidizing this layer on silicon gate 840, which derives from: (i) the implanted oxidation enhancement species; or (ii) the selectively deposited SiGe. Top oxide spacers 930A-C are multiple units of top oxide spacers 930. The oxidation of the exposed portions of silicon gate 840, does not lead to further chemical or structural modifications of Si-substrate 235; hardmasks 205A-N; mandrels 210A-N; bottom oxide spacers 630A, 630B, and 630C (i.e., the multiple units of bottom oxide spacer 630); or condensed regions 735A, 735B, and 735C (i.e., the multiple units of condensed region 735). As stated above, hardmasks 205A-N and mandrels 210A-N construct fins 125A-N, respectively. Spacers 315′ and 315″ protect fins 125A-N (i.e., hardmasks 205A-N and mandrels 210A-N) from being converted into an oxidation product during the formation of top oxide spacers 930A-C. By adding the layer containing the implanted oxidation enhancement species or the selectively deposited SiGe, the oxidation rate of a structure containing the added layer (which derives from exposed portions of silicon gate 840) is greatly enhanced in comparison to the structure not containing said added layer. In other words, the increased content of oxidation enhancement species and SiGe facilitate these enhanced oxidation rates.

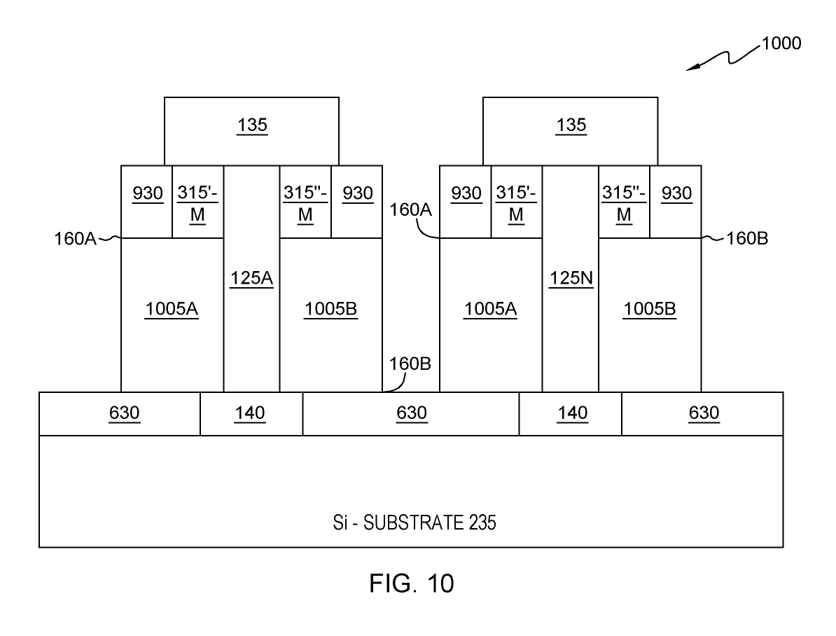

FIG. 10 is functional block diagram of the resultant VFET structure upon resuming further semiconductor fabrication processes, in accordance with an embodiment of the present invention. FIG. 10 provides only an illustration of implementation and does not imply any limitations with regard to the environments in which different embodiments may be implemented.

VFET device 1000 is a VFET-type transistor which is indirectly constructed from the following pre-cursors - structures 200, 300, 400, 500, 600, 700, 800A, and 800B and directly constructed from structures 900A and 900B. Processing 170 are performed on structures 900A and 900B to yield VFET device 1000.

VFET device 1000 contains a channel in the form of fin 125A and fin 125N to connect the source terminal (e.g., terminal 140) and the drain terminal (e.g., terminal 135). Two types of oxide spacers—bottom oxide spacer 630 and top oxide spacer 930—are adjacent to gate dielectrics 160A and 160B. This depiction is consistent with the topographical depiction in VFET 175. The sacrificial spacers—spacers 315′ and 315″—from FIG. 9A and FIG. 9B are converted to modified spacers 315′-M and 315″-M. In some embodiments, the sacrificial spacers may receive the oxidation enhancement species during ion implantation. In such cases, the sacrificial spacers—spacers 315′ and 315″—from FIG. 9A and FIG. 9B are converted and modified to yield modified spacers 315′-M and 315″-M. In other embodiments such as selective SiGe growth, the sacrificial spacers—spacers 315′ and 315″—from FIG. 9A and FIG. 9B may remain the same as spacers shown as modified spacers 315′-M and 315″-M in FIG. 10. Si-substrate 235 is the main source of silicon on which processing 170 can be performed. The top and bottom source/drain can be formed at any suitable process step by any suitable techniques. In VFET device 1000, terminal 135 is the top drain and terminal 140 is the bottom source. The bottom source/drain terminal is formed before the formation of the gate region. The top source/drain terminal is formed after the formation of the gate region. The source/drain terminals can be formed by any suitable doping technique, including but not limited to ion implantation, gas phase doping, plasma doping, plasma immersion ion implantation, cluster doping, infusion doping, liquid phase doping, solid phase doping, etc. In one embodiment, the source/drain terminals are formed by in-situ doped epitaxy.

After the forming the structures 900A and 900B, silicon gate 840 (i.e., the dummy gate, not shown in this Figure) is removed (e.g., etching or chemical modification). Specifically, the dummy silicon gate is removed to expose spacers 315′ and 315″. The exposed spacers 315′ and 315″ are subsequently removed. A portion of the removed spacers 315′ and 315″ covered by top oxide spacer 930 remains and are depicted as modified spacers 315′-M and 315″-M. Then a gate dielectric and a gate conductor are deposited. Further processes (e.g., planarization and patterning) are performed on these deposited materials to form the final gate structure—gate dielectrics 160A-B and gate conductors 1005A-B. Gate dielectric 160A is associated with gate conductor 1005A while gate dielectric 160B is associated with gate conductor 1005B.

Gate dielectrics 160A-B may include, but is not limited to: silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k may further include dopants such as lanthanum or aluminum.

Gate conductors 1005A-B can include, but is not limited to: doped polycrystalline or amorphous silicon, germanium, silicon germanium, a metal (e.g., tungsten, titanium, tantalum, ruthenium, zirconium, cobalt, copper, aluminum, lead, platinum, tin, silver, and gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, and nickel silicide), carbon nanotubes, conductive carbon, graphene, or any suitable combination of these materials. The conductive material may further comprise dopants that are incorporated during or after deposition.

The gate structure may further comprise a gate work function setting layer (not shown) between the gate dielectric and the gate conductor. The gate work function setting layer can be a metallic compound, including but not limited to: (i) nitrides (e.g., titanium nitride (TiN), hafnium nitride (HfN), hafnium silicon nitride (HfSiN), tantalum nitride (TaN), tantalum silicon nitride (TaSiN), tungsten nitride (WN), molybdenum nitride (MoN), and niobium nitride (NbN)); (ii) carbides (e.g., titanium carbide (TiC), titanium aluminum carbide (TiAlC), tantalum carbide (TaC), and hafnium carbide (HfC)); and (iii) combinations thereof.

Processes for forming gate dielectrics 160A-B and gate conductors 1005A-B include, but are not limited to, atomic layer deposition (ALD), molecular layer deposition (MLD), chemical vapor deposition (CVD), physical vapor deposition, sputtering, plating, evaporation, ion beam deposition, electron beam deposition, laser assisted deposition, chemical solution deposition, or any combination of those methods.

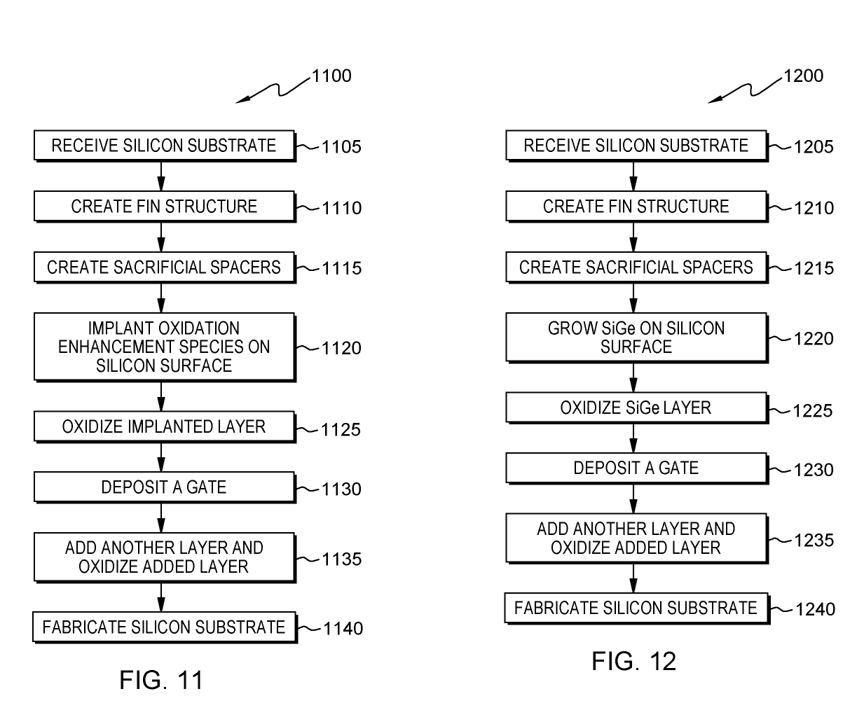

FIG. 11 is an operational flowchart to generate spacers through two oxidations, wherein an oxidation enhancement species layer is oxidized in the first oxidation, in accordance with an embodiment of the present invention.

The actor of this invention which is performing the steps of flowchart 1100 is a plurality of fabrication devices for performing the techniques with respect to processing 170.

In step 1105, processing 170 invokes a plurality of fabrication devices to receive a silicon substrate. The silicon substrate may be in the form of a wafer and/or a structure similar or identical to Si-substrate 235 as described with respect to FIG. 2.

In step 1110, processing 170 invokes a plurality of fabrication devices to create a fin structure. The actual “silicon slits” of the fin structure resemble fin 125, which is to be incorporated into channel 127. The fin structure is created on Si-substrate 235. The structure created in step 1110 is described with respect to FIG. 2.

In step 1115, processing 170 invokes a plurality of fabrication devices to create sacrificial spacers. The sacrificial spacers resemble spacers 315′ and 315″, wherein spacer 315′ is adjacent to the first wall of fin 125 and spacer 315″ is adjacent to the second wall of fin 125. Either subsequently or concomitantly, processing 170 create the bottom source and drain terminals by diffusion. The structure created in step 1115 is described with respect to FIG. 3.

In step 1120, processing 170 invokes a plurality of fabrication devices to implant oxidation enhancement species (e.g., fluorine) on silicon surfaces. An oxidation enhancement layer (e.g., OELs 430A-C) is created by implanting oxidation enhancement species (e.g., fluorine) into or onto portions of the silicon surface, as previously described with respect to FIG. 4. The structure created in step 1120 is described with respect to FIG. 4.

In step 1125, processing 170 invokes a plurality of fabrication devices to oxidize the implanted layer on the silicon surfaces. This is the first oxidation of the two oxidation steps performed in flowchart 1100. The implanted layers contain oxidation enhancement species (e.g., fluorine) from step 1120. The oxidation product of the implanted layer is an oxide spacer similar or identical to bottom oxide spacers 630A-C. Furthermore, the implanted layer is oxidized far more rapidly than other entities in order to yield bottom oxide spacers 630A-C. When the rate of oxidation of a first entity is far greater than a second entity, the oxidation of the first entity is preferred over oxidation of the second entity. Thus, the product resulting from the oxidation of the first entity would be preferred over the product resulting from the oxidation of the second entity. The rate of oxidation dictates which entity gets oxidized, the formation of the resultant products, and the distribution of resultant products. The structure created in step 1125 is described with respect to FIG. 6.

In step 1130, processing 170 invokes a plurality of fabrication devices to deposit a gate. In an exemplary embodiment, the gate is deposited onto bottom oxide spacers 630A-C, wherein the gate is a dummy silicon gate similar or identical to silicon gate 840, as previously described with respect to FIG. 8A. The structure created in step 1130 is described with respect to FIG. 8A.

In step 1135, processing 170 invokes a plurality of fabrication devices to add layer and oxidize the added layer. In one embodiment, the added layer is another oxidation enhancement layer (e.g., OELs 430A-C) created by implanting oxidation enhancement species (e.g., fluorine) onto silicon gate 840. In another embodiment, the added layer is selectively deposited SiGe onto silicon gate 840. The oxidation product of the added layer is an oxide spacer similar or identical to top oxide spacers 930A-C. Furthermore, the added layer is oxidized far more rapidly than other entities in order to yield top oxide spacers 930A-C. This is the second oxidation of the two oxidation steps performed in flowchart 1100. The structure created in step 1135 is described with respect to FIG. 9A.

In step 1140, processing 170 invokes a plurality of fabrication devices to fabricate the silicon substrate. The silicon substrate has been modified by steps 1105, 1110, 1115, 1120, 1125, 1130, and 1135 to furnish oxide spacers (e.g., bottom oxide spacers 630A-C and top oxide spacers 930A-C). Based on these resulting modifications, a VFET containing oxide spacers is created. The structure of the VFET created in step 1140 is similar or identical to VFET device 1000, as described with respect to FIG. 10.

FIG. 12 is an operational flowchart to generate spacers through two oxidations, wherein an epitaxial SiGe layer is oxidized in the first oxidation, in accordance with an embodiment of the present invention.

The actor of this invention which is performing the steps of flowchart 1100 is a plurality of fabrication devices for performing the techniques with respect to processing 170.

In step 1205, processing 170 invokes a plurality of fabrication devices to receive a silicon substrate. The silicon substrate may be in the form of a wafer and/or a structure similar or identical to Si-substrate 235 as described with respect to FIG. 2.

In step 1210, processing 170 invokes a plurality of fabrication devices to create a fin structure. The actual “silicon slits” of the fin structure resemble fin 125, which is to be incorporated into channel 127. The fin structure is created on Si-substrate 235. The structure created in step 1210 is described with respect to FIG. 2.

In step 1215, processing 170 invokes a plurality of fabrication devices to create sacrificial spacers. The sacrificial spacers resemble spacers 315′ and 315″, wherein spacer 315′ is adjacent to the first wall of fin 125 and spacer 315″ is adjacent to the second wall of fin 125. Either subsequently or concomitantly, processing 170 create the bottom source and drain terminals by diffusion. The structure created in step 1215 is described with respect to FIG. 3. (However, the created source and drain terminals are not depicted in FIG. 2)

In step 1220, processing 170 invokes a plurality of fabrication devices to grow SiGe on silicon surfaces. SiGe is grown epitaxially (e.g., SiGe layers 530A-C) onto portions of the silicon surface. Furthermore, the epitaxially grown layer is oxidized far more rapidly than other entities in order to yield bottom oxide spacers 630A-C. The structure created in step 1220 is described with respect to FIG. 5.

In step 1225, processing 170 invokes a plurality of fabrication devices to oxidize the SiGe layer. This is the first of two oxidation steps performed in flowchart 1200. The oxidation product of the epitaxial SiGe layer is an oxide spacer similar or identical to bottom oxide spacers 630A-C and a region with Ge similar or identical to condensed region 735. Furthermore, the epitaxial SiGe layer is oxidized more rapidly than other entities in order to yield bottom oxide spacers 630A-C. When the rate of oxidation of a first entity is far greater than a second entity, the oxidation of the first entity is preferred over oxidation of the second entity. Thus, the product resulting from the oxidation of the first entity would be preferred over the product resulting from the oxidation of the second entity. The rate of oxidation dictates which entity gets oxidized, the formation of the resultant products, and the distribution of resultant products. The structure created in step 1225 is described with respect to FIG. 7.

In step 1230, processing 170 invokes a plurality of fabrication devices to deposit a gate. In an exemplary embodiment, the gate is deposited onto bottom oxide spacers 630A-C, wherein the gate is a dummy silicon gate similar or identical to silicon gate 840, as previously described with respect to FIG. 8A. The structure created in step 1230 is described with respect to FIG. 8B.

In step 1235, processing 170 invokes a plurality of fabrication devices to add layer and oxidize the added layer. In one embodiment, the added layer is another oxidation enhancement layer (e.g., OELs 430A-C) created by implanting oxidation enhancement species (e.g., fluorine) onto silicon gate 840. In another embodiment, the added layer is the selectively deposited of SiGe onto silicon gate 840. The oxidation product of the added layer is an oxide spacer similar or identical to top oxide spacers 930A-C. Furthermore, the added layer is oxidized far more rapidly than other entities in order to yield top oxide spacers 930A-C. This is the second oxidation of the two oxidation steps performed in flowchart 1200. The structure created in step 1135 is described with respect to FIG. 9B.

In step 1240, processing 170 invokes a plurality of fabrication devices to fabricate the silicon substrate. The silicon substrate has been modified by steps 1205, 1210, 1215, 1220, 1225, 1230, and 1235 to furnish oxide spacers (e.g., bottom oxide spacers 630A-C and top oxide spacers 930A-C). Based on these resulting modifications, a VFET containing oxide spacers is created. The structure of the VFET created in step 1240 is similar or identical to VFET device 1000, as described with respect to FIG. 10.

What is claimed:

1. A method for depositing oxide spacers in field effect transistors, comprising:
modifying a silicon surface beneath a fin structure by implanting oxidation enhancement species onto portions of the silicon surface, wherein the fin structure contains a first wall and a second wall;
oxidizing one or more portions of the modified silicon surface into a first set of oxide spacers while maintaining an original composition of the fin structure, and un-modified portions of the silicon surface beneath the fin structure;
depositing a silicon gate structure around the one or more portions of the fin structure, wherein the silicon gate structure has a top layer, wherein the top layer is implanted with the oxidation enhancement species;
depositing silicon-germanium onto portions of the silicon surface and onto the top layer of the deposited silicon gate structure;
oxidizing the implanted the oxidation enhancement species and the deposited silicon-germanium on the top layer of the deposited silicon gate structure to form a second set of oxide spacers;
generating a region below the first set of oxide spacers containing germanium in response to oxidizing the one or more portions of the modified silicon surface into the first set of oxide spacers;
depositing silicon nitride spacers around the first wall and the second wall of the fin structure which protects the fin structure when forming the first set of oxide spacers and the second set of oxide spacers; and
converting un-modified portions of the silicon surface beneath the fin structure, the deposited silicon gate structure, the first set of oxide spacers, the second set of oxide spacers, and the silicon nitride spacers into a vertical field effect transistor, wherein the vertical field effect transistor isolates a gate region from both a source region and a drain region through the first set of oxide spacers and the second set of oxide spacers.
